(19) United States
(12) Patent Application Publication
(10) Pub. No.: US 2026/0082495 A1
(43) Pub. Date: Mar. 19, 2026

(54) Electronic Devices with Protective Cover Layers

(71) Applicant: Apple Inc., Cupertino, CA (US)

(72) Inventor: Christopher D Jones, Los Gatos, CA (US)

(21) Appl. No.: 19/232,712

(22) Filed: Jun. 9, 2025

Related U.S. Application Data
(60) Provisional application No. 63/695,770, filed on Sep. 17, 2024.

(51) Int. Cl. H05K 5/03

(52) U.S. Cl. CPC H05K 5/03

(57) ABSTRACT

A foldable electronic device may include a flexible display panel and a display cover layer that fold along a bend axis. The display cover layer may be formed from one or more glass layers. For example, a thin glass layer may form an outer surface of the display and may extend across the bend axis. A non-Newtonian material may be interposed between the glass layer and the display panel to help protect the display panel from damage when the glass layer is impacted by an external object or a drop event. The non-Newtonian layer may have a low modulus of elasticity at low strain rates (e.g., during folding and unfolding) and a high modulus of elasticity at high strain rates (e.g., when an object impacts the display) to prevent the cover glass from puncturing the underlying display layers.

This application claims the benefit of U.S. provisional patent application No. 63/695,770, filed Sep. 17, 2024, which is hereby incorporated by reference in its entirety.

### FIELD

This relates generally to electronic devices, and, more particularly, to electronic devices with displays.

### BACKGROUND

Electronic devices often have displays. Portability may be a concern for some devices, which tends to limit available real estate for displays.

### SUMMARY

An electronic device may be provided with a foldable housing that allows the device to fold and unfold about a bend axis. A flexible display may be mounted in the foldable housing. The flexible display may have an array of pixels forming a display panel. The display panel may be configured to bend along the bend axis as the device is folded.

A display cover layer may overlap the flexible display panel. The display cover layer may be formed from one or more glass layers. For example, a glass layer may form an outer surface of the display. A non-Newtonian material may be interposed between the glass layer and the display panel to help protect the display panel from damage when the glass layer is impacted by an external object or a drop event. The non-Newtonian material may be located in a groove of a glass layer, may cover a lower surface of a glass layer, may be located in a gap between first and second portions of a glass layer, or may be located elsewhere in the display.

The non-Newtonian layer may have a low modulus of elasticity at low strain rates (e.g., during folding and unfolding) and a high modulus of elasticity at high strain rates (e.g., when an object impacts the display) to prevent the cover glass from puncturing the underlying display layers.

### BRIEF DESCRIPTION OF THE DRAWINGS

FIG. 1 is a schematic diagram of an illustrative electronic device in accordance with some embodiments.

FIG. 2 is a perspective view of an illustrative electronic device with a display in accordance with some embodiments.

FIG. 3 is a side view of an illustrative electronic device in accordance with some embodiments.

FIG. 4 is a side view of an illustrative cover layer having a hinge region with a thickness that is less than the thickness of other portions of the cover layer in accordance with some embodiments.

FIG. 5 is a side view of an illustrative display having a cover layer that includes a layer of glass and one or more layers of non-Newtonian material interposed between the layer of glass and the display panel in accordance with some embodiments.

FIG. 6 is a side view of an illustrative display having a cover layer that includes a layer of non-Newtonian material interposed between an outer glass layer and a display panel in accordance with some embodiments.

FIG. 7 is a side view of an illustrative cover layer having a groove and a non-Newtonian material and a polymer material in the groove in accordance with some embodiments.

FIG. 8 is a side view of an illustrative cover layer having a groove filled with a non-Newtonian material in accordance with some embodiments.

FIG. 9 is a side view of an illustrative cover layer having a groove filled with a non-Newtonian material that spans across a lower surface of the cover layer in accordance with some embodiments.

FIG. 10 is a side view of an illustrative cover layer having an outer glass layer, an inner glass layer with a gap, and a non-Newtonian material in the gap in accordance with some embodiments.

FIG. 11 is a side view of an illustrative cover layer having a glass layer with uniform thickness and a non-Newtonian material that spans across a lower surface of the glass layer in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., diodes formed from crystalline semiconductor dies).

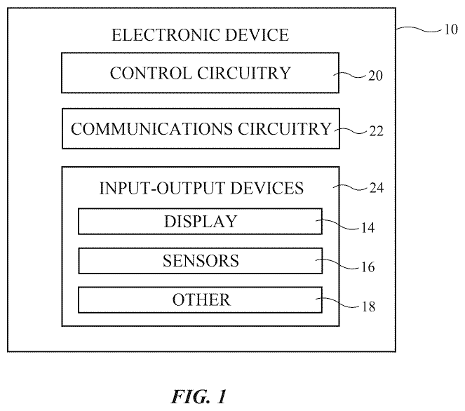

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display.

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

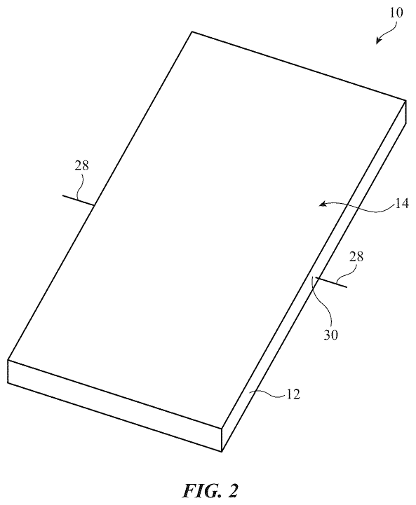

FIG. 2 is a perspective view of electronic device 10 in an illustrative configuration in which device 10 is a portable electronic device such as a cellular telephone or tablet computer. As shown in FIG. 2, device 10 may have a display such as display 14. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometimes be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Housing 12 may have flexible structures (e.g., bendable housing wall structures) and/or hinge structures such as hinge 30. Hinge 30 may have a hinge axis aligned with device bend axis 28. Hinge 30 and/or flexible housing structures that overlap bend axis 28 may allow housing 12 to bend about bend axis 28. For example, housing 12 may have a first portion on one side of bend axis 28 and a second portion on an opposing side of bend axis 28 and these two housing portions may be coupled by hinge 30 for rotational motion about axis 28.

As housing 12 is bent about bend axis 28, the flexibility of display 14 allows display 14 to bend about axis 28. In an illustrative configuration, housing 12 and display 14 may bend by 180°. This allows display 14 to be folded back on itself (with first and second outwardly-facing portions of display 14 facing each other). The ability to place device 10 in a folded configuration in this way may help make device 10 compact so that device 10 can be stored efficiently. When it is desired to view images on display 14, device 10 may be unfolded about axis 28 to place device 10 in the unfolded configuration of FIG. 2. This allows display 14 to lie flat and allows a user to view flat images on display 14. The ability to fold display 14 onto itself allows device 10 to exhibit an inwardly folding behavior. Display 14 may be sufficiently flexible to allow device 10 to be folded outwardly and/or inwardly.

Device 10 of FIG. 2 has a rectangular outline (rectangular periphery) with four corners. As shown in FIG. 2, a first pair of parallel edges (e.g., the left and right edges of device 10 in the example of FIG. 2) may be longer than a second pair of parallel edges (e.g., the upper and lower edges of device 10 of FIG. 2) that are oriented at right angles to the first pair of parallel edges. In this type of configuration, housing 12 is elongated along a longitudinal axis that is perpendicular to bend axis 28. Housing 12 may have other shapes, if desired (e.g., shapes in which housing 12 has a longitudinal axis that extends parallel to bend axis 28). With an arrangement of the type shown in FIG. 2, the length of device 10 along its longitudinal axis may be reduced by folding device 10 about axis 28.

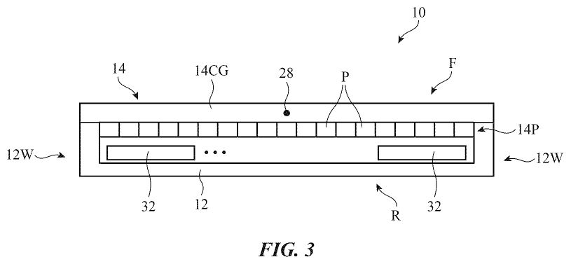

FIG. 3 is a cross-sectional side view of an illustrative foldable electronic device. Device 10 of FIG. 3 may bend about bend axis 28. Bend axis 28 may be aligned with display cover layer 14CG or other structures in device 10. For example, bend axis 28 may pass through a portion of display cover layer 14CG or may be located above or below layer 14CG.

As shown in FIG. 3, display 14 includes an array of pixels P forming display panel 14P under an inwardly facing surface of display cover layer 14CG. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures.

Display cover layer 14CG may be formed from polymer, glass, crystalline materials such as sapphire, other materials, and/or combinations of these materials. To enhance flexibility, a portion of layer 14CG that overlaps bend axis 28 may be locally thinned (e.g., this portion may be thinned relative to portions of layer 14CG that do not overlap bend axis 28). The thickness of layer 14CG (e.g., the non-thinned portions of layer 14CG) may be 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness.

In the example of FIG. 3, housing 12 has a portion on rear face R that forms a rear housing wall and has side portions forming sidewalls 12W. The rear housing wall of housing 12 may form a support layer for components in device 10. Housing 12 may also have one or more interior supporting layers (e.g., frame structures such as an optional midplate, etc.). These interior supporting layers and the rear housing wall may have first and second portions that are coupled to opposing sides of a hinge that is aligned with bend axis 28 (see, e.g., hinge 30 of FIG. 2) or may be sufficiently flexible to bend around bend axis 28.

Electrical components 32 may be mounted in the interior of device 10 (e.g., between display 14 and the rear of housing 12. Components 32 may include circuitry of the type shown in FIG. 1 (e.g., control circuitry 20, communications circuitry 22, input-output devices 24, batteries, etc.). Display 14 may be mounted on front face F of device 10. When device 10 is folded about axis 28, display cover layer 14CG, display panel 14P, and the other structures of device 10 that overlap bend axis 28 may flex and bend to accommodate folding.

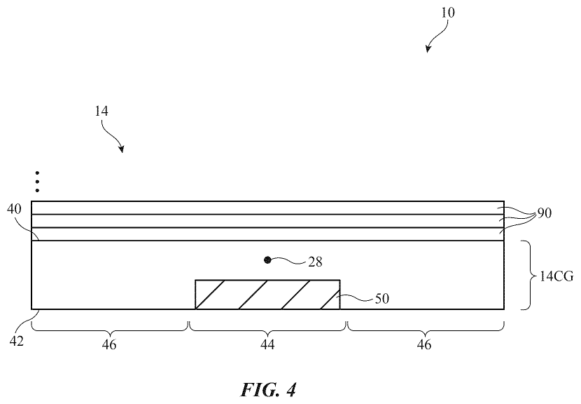

In some arrangements, the outer and/or inner surfaces of display cover layer 14GC may be provided with coatings. These coatings may include, for example, antireflection coatings, anti-scratch coatings, anti-smudge coatings, and/or other coating layers. Consider, as an example, the cross-sectional side view of display cover layer 14CG of FIG. 4. As shown in FIG. 4, display cover layer 14CG may have an outer surface (outwardly facing surface) such as surface 40 and an opposing inner surface (inwardly facing surface) such as surface 42. A strip-shaped region of display cover layer 14CG that overlaps and runs parallel to bend axis 28 may have a locally reduced thickness (e.g., a groove or other recess that runs parallel to bend axis 28 may be formed in layer 14CG to form locally reduced thickness portion 44 of layer 14CG). Locally reduced thickness portion 44 of layer 14CG may be thinner than other portions of layer 14CG such as portions 46 (which may be, for example, planar glass layer portions of layer 14CG). The presence of reduced thickness portion 44 in display cover layer 14CG may facilitate bending of display cover layer 14CG about bend axis 28.

To help planarize inner surface 42 and thereby facilitate mounting of display panel 14P against inner surface 42 (e.g., with a layer of adhesive), the elongated recess (groove) in the inner surface of layer 14CG that forms thinned portion 44 may be filled with a polymer such as polymer 50. Polymer 50 may be sufficiently flexible to bend about bend axis 28 when device 10 is opened and closed. The refractive index of polymer 50 may be matched to that of display cover layer 14CG to help minimize light reflections (e.g., by incorporating inorganic nanoparticles in polymer 50). For example, at a wavelength of 500 nm, the refractive index of polymer 50 may differ from that of layer 14CG by less than 0.15, less than 0.1, or less than 0.05 (as examples).

Coating layers 90 may optionally be formed on outer surface 40. Coating layers 90 may include, for example, anti-scratch layers (sometimes referred to as hard coats), protective polymer layers, anti-smudge layers, anti-fog layers, antireflection layers, anti-static layers, adhesion layers, and/or other coatings. In some configurations, each of these functions may be implemented using a separate respective coating layer. In other configurations, a single layer may serve multiple functions. In general, coatings such as coatings 90 may be formed on outer surface 40 and/or inner surface 42. In the illustrative configuration of FIG. 4, coatings 90 are formed on outer surface 40.

Coatings 90 may be provided in any suitable order. As one example, the lowermost coating of coatings 90 (e.g., a coating layer formed directly on surface 40 of FIG. 4) may be a hard coat or other anti-scratch layer that helps prevent scratches that could damage layer 14CG. An antireflection coating may be formed on top of the anti-scratch layer. The antireflection layer may be a thin-film interference filter antireflection coating containing a stack of thin-film layers such as dielectric sublayers of alternating refractive index. One of the thin-film layers may be a conductive layer such as a transparent semiconductor layer (e.g., an indium tin oxide layer) that serves as an antistatic layer. An anti-smudge coating or anti-fog coating may be formed on top of the antireflection layer. Anti-smudge coatings (e.g., hydrophobic polymer coatings) may help reduce fingerprints and other undesired marks on the surfaces of display 14. An example of an anti-smudge coating is a fluoropolymer coating (e.g., a fluoropolymer formed from evaporated perfluoropolyether) that serves as an oleophobic layer. Fluoropolymers can be adhered to underlying coating layers using an intervening adhesion layer.

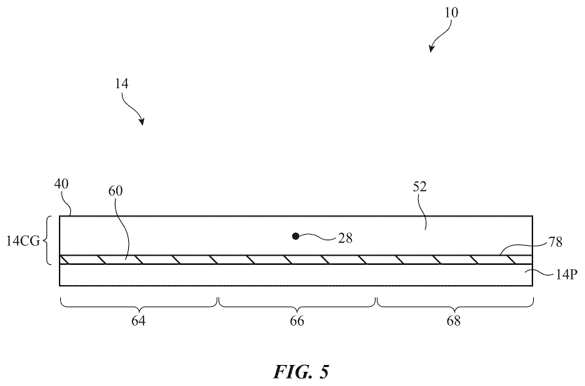

In some configurations, one or more of coatings 90 may be omitted and the outermost surface of display 14 may be formed from bare glass. This type of arrangement is illustrated in FIG. 5.

As shown in FIG. 5, display 14 may include display panel 14P and cover layer 14CG overlapping display panel 14P. Display 14 may include first portion 64 and second portion 68 joined by bendable portion 66. Bendable portion 66 overlaps bend axis 28 and is configured to bend as device 10 is folded and unfolded. As device 10 is folded and unfolded and portion 66 bends, first portion 64 of display 14 may rotate relative to second portion 68 of display 14. If desired, first portion 64 and second portion 68 of display panel 14P and cover layer 14CG may remain planar or substantially planar as device 10 is folded and unfolded, while portion 66 of display panel 14P and cover layer 14CG may bend and flex as device 10 is moved between folded and unfolded configurations.

Cover layer 14CG may include one or more transparent layers such as outer transparent layer 52. Outer transparent layer 52 may be formed from glass, polymer, sapphire, and/or any other suitable material. Arrangements in which layer 52 is formed from glass are sometimes described herein as an illustrative example. Glass layer 52 may form an outermost surface of display 14 and device 10. When display 14 has bare glass on its outer surface (e.g., without an overlapping protective polymer layer), care must be taken to ensure that objects impacting display 14 do not cause damage to cover layer 14CG and the underlying display panel 14P. Additional display protection can be provided by increasing the thickness of cover layer 14CG, but this may prevent cover layer 14CG from achieving the desired bending radius (e.g., a bending radius of 100 microns or less).

To maintain the desired bending radius while providing additional protection for display panel 14P, cover layer 14CG may include one or more layers of non-Newtonian material such as non-Newtonian material 60. Non-Newtonian material 60 may be located on either or both sides of outer glass layer 52. In the example of FIG. 5, non-Newtonian material 60 is interposed between display panel 14P and outer glass layer 52 to prevent outer glass layer 52 from damaging display panel 14P when outer glass layer 52 is impacted by an external object or a drop event. Non-Newtonian material 60 may have a stress-rate-dependent modulus of elasticity, may have a viscosity that is shear-rate dependent, and/or may otherwise exhibit a non-linear relationship between shear stress and shear rate. At lower stress rates (e.g., when device 10 is being folded or unfolded), non-Newtonian material 60 may have a lower modulus of elasticity and may be configured to bend. This allows non-Newtonian material 60 to bend and flex as device 10 is folded and unfolded. At higher stress rates (e.g., during a drop event and/or when an object impacts glass layer 52), non-Newtonian material 60 may have a higher modulus of elasticity and may become stiff, thereby providing protection for display panel 14P when an object places sharp pressure on display 14. Non-Newtonian material 60 may be a polymer (e.g., polysiloxane or other suitable polymer material) or may be any other suitable material that exhibits non-Newtonian behavior such as a shear-rate dependent viscosity.

In the example of FIG. 5, non-Newtonian material 60 spans across first portion 64, bendable portion 66, and second portion 68 of display 14. This is merely illustrative. If desired, non-Newtonian material 60 may be located only in bendable portion 66 and may be omitted from first portion 64 and second portion 68. Non-Newtonian material 60 may have a variable thickness or may have uniform thickness across portions 64, 66, and 68. Non-Newtonian material 60 may be located on lower surface 78 of outer glass layer 52 (as shown in the example of FIG. 5), and/or may be located in one or more grooves or gaps in outer glass layer 52. If desired, cover layer 14CG may include more than one layer of non-Newtonian material 60.

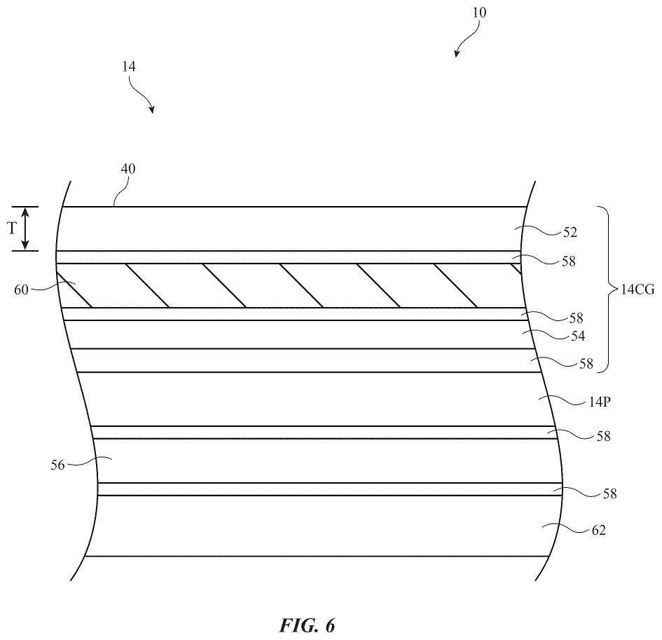

FIG. 6 is a side view of device 10 showing illustrative layers that may be included in display 14. As shown in FIG. 6, cover layer 14CG may overlap display panel 14P. Display panel 14P may be interposed between cover layer CG and one or more stiff backing layers such as backplate 62. Backplate 62 may be formed from metal or other stiff material and may support portions 64 and 68 of display 14. If desired, backplate 62 may be omitted from bendable region 66, may have a reduced thickness in bendable region 66, or may have other features that permit display 14 to bend in region 66. If desired, one or more polymer layers such as polymer layer 56 may be attached between display panel 14P and backplate 62 using adhesive layers such as transparent adhesive 58.

Cover layer 14CG may include outer glass layer 52, non-Newtonian material 60, one or more polymer layers such as polymer layer 54 (e.g., polyethylene terephthalate or other suitable polymer), and one or more optically clear adhesive layers such as adhesive 58. Adhesive layers 58 may be located between outer glass layer 52 and non-Newtonian material 60, between non-Newtonian material 60 and polymer layer 54, and between polymer layer 54 and display panel 14P, if desired. In some arrangements, one or more of adhesive layers 58 may be formed from a non-Newtonian material (e.g., material 60) to provide additional display protection between outer glass layer 52 and display panel 14P.

In the example of FIG. 6, non-Newtonian material 60 is interposed between outer glass layer 52 and polymer layer 54. This is merely illustrative. If desired, non-Newtonian material 60 may be interposed between polymer layer 54 and display panel 14P, may be located on exterior surface 40 of outer glass layer 52, may be located directly on display panel 14P, and/or may be located elsewhere in display 14. Non-Newtonian material 60 may span across the entirety of display 14 or may only be located in certain regions of display 14 (e.g., portion 64, portion 66, and/or portion 68 of FIG. 5). In general, placing non-Newtonian material 60 in any location between display panel 14P and outer glass layer 52 will help prevent outer glass layer 52 from damaging display panel 14P when impacted by an external object.

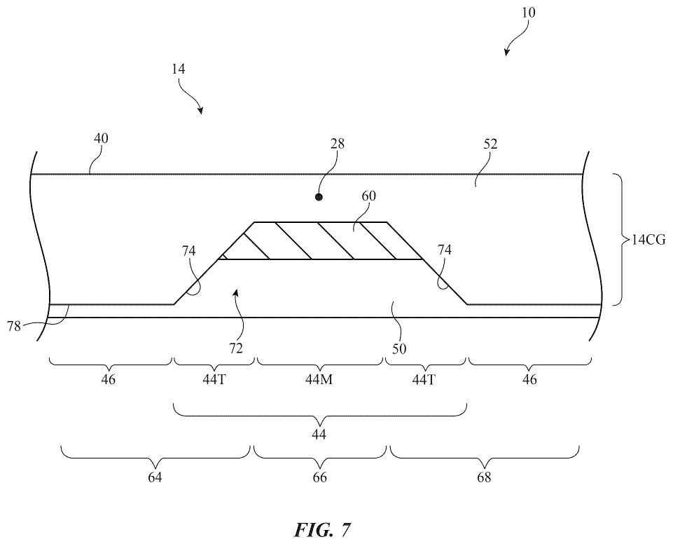

In the example of FIG. 7, outer glass layer 52 of display 14 has a variable thickness to facilitate bending of glass layer 52. In particular, cover layer 14CG may include a groove such groove 72 that overlaps and runs parallel to bend axis 28 to form a strip-shaped locally reduced thickness portion 44 in glass layer 52. Locally reduced thickness portion 44 of layer 52 may be thinner than other portions of layer 52 such as portions 46 (which may be, for example, planar glass layer portions of layer 52). The presence of reduced thickness portion 44 in glass layer 52 may facilitate bending of glass layer 52 about bend axis 28.

It may be desirable to configure the cross-sectional profile of glass layer 52 of display cover layer 14CG to help avoid distortion of the image on display panel 14P due to changes in the refraction of light from thickness variations in glass layer 52. As shown in FIG. 7, for example, glass layer 52 may include tapered edges such as tapered edges 74 on opposing sides of groove 72. Tapered edges 74 of glass layer 52 may form sloped sidewalls on opposing sides of groove 72 that provide locally reduced thickness region 44 of glass layer 52 with varying thickness portions 44T. Portions 44T may be tapered and characterized by smoothly and gradually varying thicknesses. Portions 44T may be located at the outer edges of locally reduced thickness region 44 and may provide layer 52 with a gradual transition between the thinnest part of layer 52 (e.g., portion 44M of portion 44 of layer 52, which forms part of bendable region 66 of display 14) and the thicker portions of layer 52 such as portions 46 (e.g., portions 46 of layer 52 which are located in first portion 64 and second portion 68 of display 14). By gradually changing the thickness of glass layer 52, undesired visual artifacts and stress concentration features may be avoided.

As shown in FIG. 7, non-Newtonian material 60 may be formed in groove 72 of glass layer 52. Non-Newtonian material 60 may fill groove 72 completely or may only partially fill groove 72. Non-Newtonian material 60 may serve as a protective layer between glass 52 and display panel 14P. When stress is applied at lower rates, such as during opening and closing of device 10, non-Newtonian material 60 may have a lower modulus of elasticity and may bend and flex to accommodate folding of display 14. When stress is applied at higher rates, such as during a drop event or when an external object suddenly impacts display 14, non-Newtonian material 60 may have a higher modulus of elasticity and may become stiff. This in turn helps reduce displacement of glass 52 in high strain rate events so that display panel 14P is protected from damage.

To provide a planar surface and thereby facilitate mounting of display panel 14P to cover layer 14CG, groove 72 in the inner surface of layer 52 that forms thinned portion 44 may be filled with a polymer such as polymer 50. Polymer 50 may be sufficiently flexible to bend about bend axis 28 when device 10 is opened and closed. The refractive index of polymer 50 may be matched to that of glass layer 52 and/or may be matched to that of non-Newtonian material 60 to help minimize light reflections (e.g., by incorporating inorganic nanoparticles in polymer 50). For example, at a wavelength of 500 nm, the refractive index of polymer 50 may differ from that of layer 52 and/or layer 60 by less than 0.15, less than 0.1, or less than 0.05 (as examples). If desired, polymer 50 may be located only in groove 72 or may also be located on the lower surface 78 of glass 52.

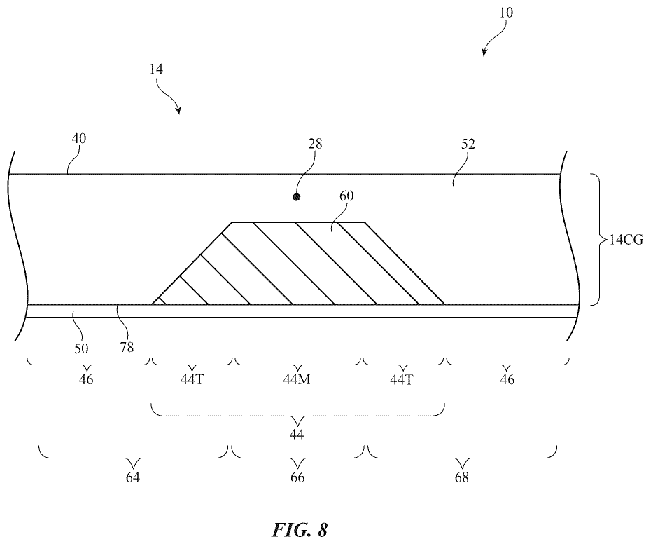

In the example of FIG. 8, non-Newtonian material 60 fills the entirety of groove 72 and forms a planar surface at lower surface 78 of glass layer 52. If desired, polymer 50 may be omitted or may be formed on lower surface 78 of glass 52. Polymer 50 may, for example, span across portions 64, 66, and 68 of display 14.

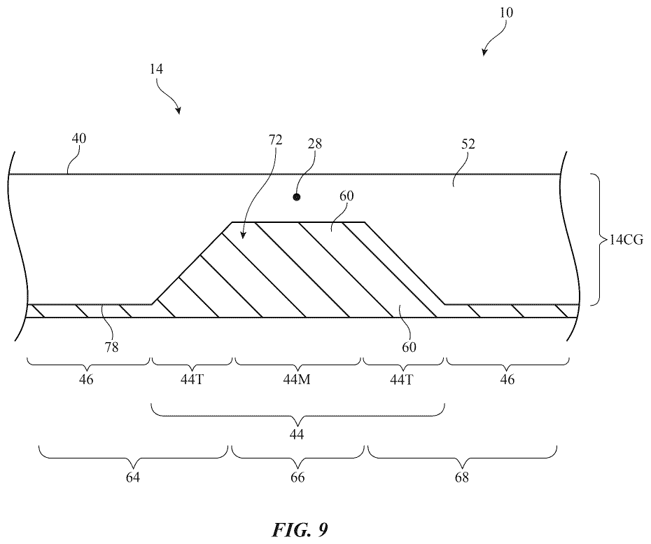

The examples of FIGS. 7 and 8 in which non-Newtonian material 60 is located only in groove 72 of glass layer 52 are merely illustrative. If desired, non-Newtonian material 60 may span across lower surface 78 of glass 52, as shown in FIG. 9. In the example of FIG. 9, non-Newtonian material 60 fills groove 72 and covers lower surface 78 of glass layer 52, spanning across portions 64, 66, and 68 of display 14.

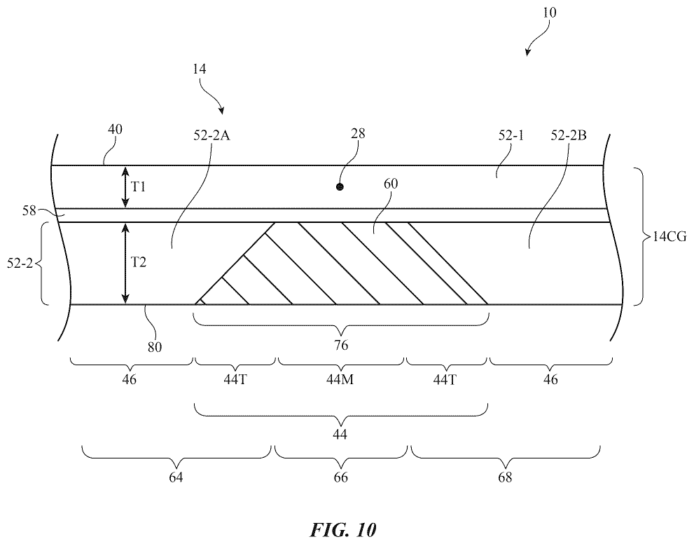

The examples of FIGS. 7, 8, and 9 in which a single layer of glass is used to provide cover layer 14CG with regions of variable thickness is merely illustrative. If desired, cover layer 14CG may include multiple layers of glass to provide cover layer 14CG with regions of variable thickness. This type of arrangement is illustrated in FIG. 10.

As shown in FIG. 10, cover layer 14CG may include multiple layers such as outer glass layer 52-1 and inner glass layer 52-2. Outer layer 52-1 may extend across fold axis 28 and may have uniform thickness T1 across portions 64, 66, and 68. For example, thickness T1 of outer layer 52-1 may be less than 100 microns, less than 200 microns, less than 400 microns, or greater than 400 microns. Thickness T1 of outer layer 52-1 may be sufficiently small to permit outer layer 52-1 to bend in portion 66 overlapping hinge axis 28.

Inner layer 52-2 may include first and second portions 52-2A and 52-2B in regions 46 separated by gap 76 in region 44. Gap 76 may be a recess that extends partway through layer 52-2 or may be a through-hole that extends entirely through layer 52-2. Gap 76 may overlap hinge axis 28, thereby allowing first portion 52-2A to move relative to portion 52-2B of layer 52-2 as display 14 is folded and unfolded. First and second portions 52-2A and 52-2B of layer 52-2 may have uniform thickness T2. Thickness T2 may be equal to or different than thickness T1 of layer 52-1. For example, thickness T2 may be less than 100 microns, less than 200 microns, less than 400 microns, or greater than 400 microns. Since layer 52-2 includes gap 76 overlapping hinge axis 28 and does not need to bend, layer 52-2 may have a greater thickness than layer 52-1, if desired.

In some arrangements, outer layer 52-1 may be a first type of glass and inner layer 52-2 may be a second type of glass having one or more different properties than outer glass 52-1. For example, inner layer 52-2 may have a higher modulus of elasticity than outer layer 52-1, may exhibit lower compressive stress than outer layer 52-1, may have a greater thickness than outer layer 52-1, may have a different refractive index than outer layer 52-1 (e.g., a refractive index that more closely matches that of polymer 50), and/or may have other properties that differ from those of outer layer 52-1. The presence of layer 52-2 in regions 46 may help protect display panel 14P from damage during operation of device 10. For example, if a sharp object or drop event causes damage to outer layer 52-1, the presence of a stiffer layer behind outer layer 52-1 such as inner layer 52-2 may help prevent the puncture from reaching display panel 14P. This allows outer layer 52-1 to be sufficiently thin to achieve the desired bending radius of cover layer 14CG (e.g., a bending radius of 100 microns or less). Additionally, since layers 52-1 and 52-2 are separate layers (as opposed to a monolithic piece of glass with variable thickness), outer glass layer 52-1 may be formed with uniform thickness across regions 46 and 44, which helps prevent variations in the amount of expansion that occurs across portions 46 and 44 of layer 52-1 during ion exchange. If desired, polymer material 50 may optionally be formed on lower surface 80 of inner glass layer 52-2.

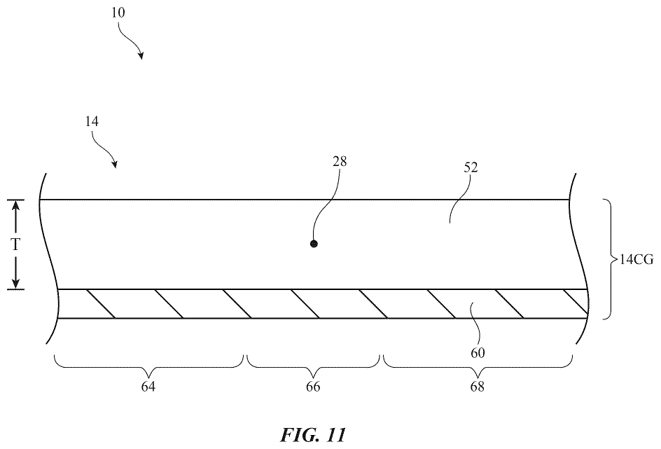

In the example of FIG. 11, cover layer 14CG includes a single glass layer 52 with uniform thickness T across regions 64, 66, and 68. For example, thickness T of glass layer 52 may be less than 100 microns, less than 200 microns, less than 400 microns, or greater than 400 microns. Thickness T of glass layer 52 may be sufficiently small to permit glass layer 52 to bend in portion 66 overlapping hinge axis 28.

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made to the described embodiments. The foregoing embodiments may be implemented individually or in any combination.

What is claimed is:

1. An electronic device, comprising:
a foldable housing that is configured to bend about a bend axis;
a flexible display panel that overlaps the bend axis; and
a display cover layer that overlaps the flexible display panel, wherein the display cover layer comprises:
a glass layer that extends across the bend axis; and
a non-Newtonian material interposed between the glass layer and the flexible display panel.

2. The electronic device defined in claim 1 wherein the glass layer has first and second opposing surfaces and wherein the non-Newtonian material is adhered to the second surface.

3. The electronic device defined in claim 1 wherein the glass layer has a groove that overlaps and extends parallel to the bend axis and wherein the non-Newtonian material is located in the groove.

4. The electronic device defined in claim 3 further comprising a transparent polymer in the groove, wherein the non-Newtonian material is interposed between the glass layer and the transparent polymer.

5. The electronic device defined in claim 3 wherein the non-Newtonian material fills the groove and covers a lower surface of the glass layer facing the display panel.

6. The electronic device defined in claim 3 further comprising a transparent polymer that covers a lower surface of the glass layer facing the display panel.

7. The electronic device defined in claim 1 wherein the display cover layer comprises an additional glass layer interposed between the glass layer and the display panel and wherein the glass layer has uniform thickness.

8. The electronic device defined in claim 7 wherein the additional glass layer has first and second portions separated by a gap that is aligned with the bend axis, wherein the non-Newtonian material is located in the gap.

9. The electronic device defined in claim 1 wherein the glass layer has first and second portions joined by a bendable portion that overlaps the bend axis and wherein the non-Newtonian material overlaps the first and second portions and the bendable portion.

10. The electronic device defined in claim 1 wherein the non-Newtonian material comprises a polymer material having a stress-rate-dependent modulus of elasticity.

11. A display, comprising:
a flexible display panel having first and second portions that fold relative to one another about a fold axis; and
a cover layer through which the flexible display panel displays images, wherein the cover layer comprises:
a glass layer that forms an outer surface of the display, wherein the glass layer overlaps the fold axis; and
a non-Newtonian polymer layer interposed between the flexible display panel and the glass layer.

12. The display defined in claim 11 wherein the non-Newtonian polymer layer overlaps the fold axis and the first and second portions of the flexible display panel.

13. The display defined in claim 11 wherein the glass layer has first and second regions joined by a bendable region that overlaps the fold axis and wherein the bendable region has a smaller thickness than the first and second regions.

14. The display defined in claim 11 wherein the glass layer has a groove and wherein the non-Newtonian polymer layer is located in the groove.

15. The display defined in claim 11 further comprising a transparent polymer interposed between the non-Newtonian polymer layer and the display panel, wherein the non-Newtonian polymer layer has a stress-rate-dependent modulus of elasticity.

16. A foldable electronic device that folds along an axis, comprising:
a display panel having first and second display regions that fold relative to one another about the axis;
a cover layer that covers the first and second display regions and that extends across the axis, wherein the cover layer has a groove aligned with and parallel to the axis; and
a non-Newtonian material in the groove.

17. The foldable electronic device defined in claim 16 wherein the cover layer comprises a layer of glass in which the groove is formed and wherein the non-Newtonian material is interposed between the layer of glass and the display panel.

18. The foldable electronic device defined in claim 17 wherein the layer of glass has first and second opposing surfaces, wherein the first surface forms an outer surface of the foldable electronic device, and wherein the non-Newtonian material covers the second surface.

19. The foldable electronic device defined in claim 17 further comprising a transparent polymer in the groove.

20. The foldable electronic device defined in claim 17 wherein the layer of glass has sloped sidewalls on opposing sides of the groove.
